(19) United States
(12) Patent Application Publication
(10) Pub. No.: US 2016/0286688 A1
(43) Pub. Date: Sep. 29, 2016

(54) Cooling Method for Computer System

(71) Applicants: Banqiu Wu, San Jose, CA (US); Ming Xu, San Jose, CA (US)

(72) Inventors: Banqiu Wu, San Jose, CA (US); Ming Xu, San Jose, CA (US)

(21) Appl. No.: 14/670,405

(22) Filed: Mar. 26, 2015

(51) Int. Cl. H05K 7/20; F24F 5/00

(52) U.S. Cl. CPC H05K 7/2079; F24F 5/0046; F24F 2005/0053

(57) ABSTRACT

A computer system (taking server as an example) is cooled by using liquid coolants such as water, oil, and ionic liquid. Liquid coolant flows in a closed coolant conduit which is configured thermally to contact heat-generating components and a liquid-liquid heat exchanger. The heat generated in computer chips is carried out by liquid coolant and dissipated to heat exchanger where cooling water dissipates heat to large water body. For economic stable operation, cooling water is pumped from large water body such as river to a water tower where water level kept constant to ensure heat exchanger work at optimal condition. The simple and effective approach for computer system cooling provided in this disclosure is a cost-effective data center efficiency solution.

### FIELD

The embodiment of present invention is generally related to liquid cooling system for heat-generating components of computers. More specifically, the present invention relates liquid cooling system in computer systems used in data center.

### BACKGROUND

In our information age, data centers for internet and mobile devices are the most critical components because they store, share, and transfer data for varieties of applications. Data centers serve industries, civil communications, military and defense applications, and transportations. Data centers consist of multiple computers usually called servers and switches. Both of them use very large number of integrated circuits (ICs). When a computer works, ICs will change status, or change the on-and-off status, which consumes electricity and generates significant heat. Even when computer system is at idle condition, it still consumes electricity due to the current leakage and circuit requirement.

Multiple servers are accommodated in a server rack at data center. Each computer consumes significant electricity. It is common for a server (computer) to consume over a hundred watts. In a server rack, i.e. a module of servers, there are multiple computers. Similarly, there are many server racks in a data center. Therefore, a data center consumes large amount of electricity and a large data center consumes the same amount of electricity as a small or medium size town. Among the contributions to the electricity consumption, most electricity is consumed by servers and their cooling systems. It is quite often that cooling system uses the same amount of electricity as the server computers. It is estimated that the date centers consume about two percent of total electricity generated worldwide.

Power usage effectiveness (PUE) is usually used to measure the efficiency of a data center. It is defined as a ratio of total energy used by facility to that used by information technology (IT) equipment. An ideal PUE is 1.0, but average PUE worldwide now is about 2.0 although some data center claims their PUE is significantly below 2.0. The average PUE value of 2.0 indicates the necessity to improve the data center cooling effectiveness. One approach to improve the cooling efficiency is to use water cooling to replace current air cooling. In the past, water cooling was used for large scale computers, but did not obtain large scale application for personal computers or servers in data center because of its limitation by the shape of heat-generating components and thus the complexity.

As the dimensions of integrated circuit components decrease, more components are compacted in a given area of a semiconductor integrated circuit. Accordingly, more transistors are held on a given area and thus more heat is generated in the same area. In order to keep the IC temperature in allowed range for proper performance, heat generated has to be transferred out of integrated circuit effectively and economically. With the internet getting popular, more and more servers are installed and in service to support the internet function. The trend of applications of more mobile devices and cloudy technology will drive more electricity consumption at data centers in the future.

Current servers are located in an air-conditioner-regulated environment, usually in a specially designed building. The heat generated by microprocessors, memory chips, and power supply chips is released locally, which is like a large heater in a room cooled by air conditioner. Due to the low efficiency of air conditioner, the cooling system uses lots of electricity, occupies large footprints, and causes high costs.

Accordingly, it is very significant to provide an effective method to reduce cooling power and improve cooling efficiency for computer system, especially for the system with large number of computers such as data center. Cooling technology now becomes an enabler to improve data center efficiency.

Improving cooling system in data center not only saves energy consumption, but also benefits ecological and environmental systems. A few percent reduction of electricity consumption in data center cooling system will significantly decrease the emission of carbon dioxide amount, which equivalents to shut down multiple coal power plants with environmental benefit in addition to the cost reduction.

The heat generated in electronic devices in a data center has to be transferred outside the accommodating construction and dissipated to environment, which consumes tremendous electricity. In order to prevent the overheat of ICs, the surface of the ICs should be kept not very high, which means the temperature difference between high temperature source (IC surface) and low temperature environment will be significant low, resulting in the challenge in engineering realization and high costs in cooling system.

Traditionally, heat-generating components in computers are cooled by cold air supplied by air-conditioners. The air in server's building exchanges and dissipates heat on chiller's cold surface. By applying work, air conditioners transfer heat from a cold surface to a hot surface, and thus heat is dissipated to air outside the building by heat exchanging. This cooling method is accompanied with uses of lots of compressors and fans, and thus consumes significant electricity because of the low efficiency and high costs for air conditioning system.

In order to lower the cost of using air conditioner, cold air is used to directly cool the heat generating components in winter at north areas. However, the air humanity has to be controlled well and the application is also limited by weather and season.

Similarly, lots of power is used by fans in the server rack to dissipate heat from component surface to air by blowing air through the server rack, which also consumes significant energy, makes noise, and has low efficiency.

In order to overcome low efficient challenge in air cooling problems, water is used for cooling the heat-generating components. Current heat-generating components are mainly microprocessor unit (MPU), dynamic random-access memory (DRAM), and power chips. Microprocessor has a flat shape and it is relatively easy to use liquid cooling on a flat surface. However, it is difficult to use liquid cooling on DRAM dual in-line memory module (DIMM) due to the irregular shape although some attempts were tried.

In order to overcome the intrinsic problem mentioned above, liquid cooling was used by circulating liquid coolant on the surface of ICs to improve the efficiency. However, this method has to use chillers to cool the liquid, resulting in a low cooling efficiency.

In order to use natural water body for data center cooling, air cooling of server rack was combined with heat dissipation to large natural water bodies such as ocean, river, and lake. This approach may be the lowest data center operating cost and has the best potential for future application. However, there are lots of challenges for the realization of this method. Therefore, some novel method is disclosed in this invention for improving server cooling and data center efficiency.

### SUMMARY

Methods for improving cooling efficiency and reducing cooling costs for large number of computer system are provided herein. In some embodiments, a method of improving cooling efficiency and reducing cooling costs for a large number of computer systems includes: (a) circulating a first liquid coolant to dissipate heat from heat-generating components such as microprocessors, memory chips, and power chips to the first liquid coolant; (b) heat-dissipating from the first coolant to a large water body such as river, reservoir, and ocean.

There are a first coolant supply conduit and a first coolant return conduit, the former supplies the first coolant to heat-generating components in servers, and the latter carries the heated first coolant out of heat-generating components in servers for heat exchange and thus dissipates heat to a second coolant in the heat exchanger so that the first coolant can be reused by circulation in a closed loop.

The most important thing for a reliable cooling performance is to keep the flow rate controllable in the cooling conduit on the heat-generating components. This is enabled by controlling the pressure in the supply conduit by using an in-line pump, large ratio of cross-sectional area of supply conduit to the sum of cooling conduit cross-sectional areas on the heat-generating components. The large cross-sectional area of supply conduit determines the constant pressure of first liquid coolant and then the constant flow rates in cooling conduit on each heat-generating component, and then uniform cooling performance on every heat-generating component.

In one embodiment, liquid-liquid heat exchanger is used to dissipate heat finally to large water body. The water from large water body as a second liquid coolant needs to be pretreatment before used for cooling such as filtration to remove particles. After the pretreatment, the second coolant from the large water body will be pumped to a water tower where water surface level is maintained constant so that the water pressure on the outlet is kept constant, resulting in a constant delivery water pressure. After the second liquid coolant is used in heat exchanger, the only change is the little rise in temperature such as a few degrees. This discharge water is environmentally benign so that it can be returned to the large water body. For cooling performance controlling, the valves are used on the conduit of the second liquid coolant so that the flow rate can be effectively controlled. For automatic control of the cooling performance, temperature sensors are disposed on the conduit of the second liquid coolant to feedback data for controlling the opening of the valves.

In winter season of north area, temperature is so low that water in the large water body may freeze. In order to avoid possible damage on conduit caused by freezing, the conduit of the second liquid coolant should have good protection such as underground arrangement. Such ideas are also applicable to other related parts such as pumps.

Sucking of water by pump from the large water body is impacted by the water level elevation, especially when the large water body is a river. Special caution should be paid for adjustment of the relative conduit location and prevention of freeze in winter.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depict one embodiment of computer cooling system in accordance with one embodiment of the invention;

FIG. 2 depicts a schematic view of a chip cooling method that may be utilized to cool the computer in accordance with one embodiment of the present invention.

### DETAILED DESCRIPTION

Embodiments of the present invention generally provide apparatus and methods for removing heat from a computer system. Particularly, embodiments of the present invention provide methods and apparatus for removing heat from the integrated circuit directly in the computer system. In one embodiment, a cooling liquid is disposed contacting to the heat-generating components. The heat is carried out of the electronic device by cooling liquid and dissipated to a large water body such as river, reservoir, or ocean.

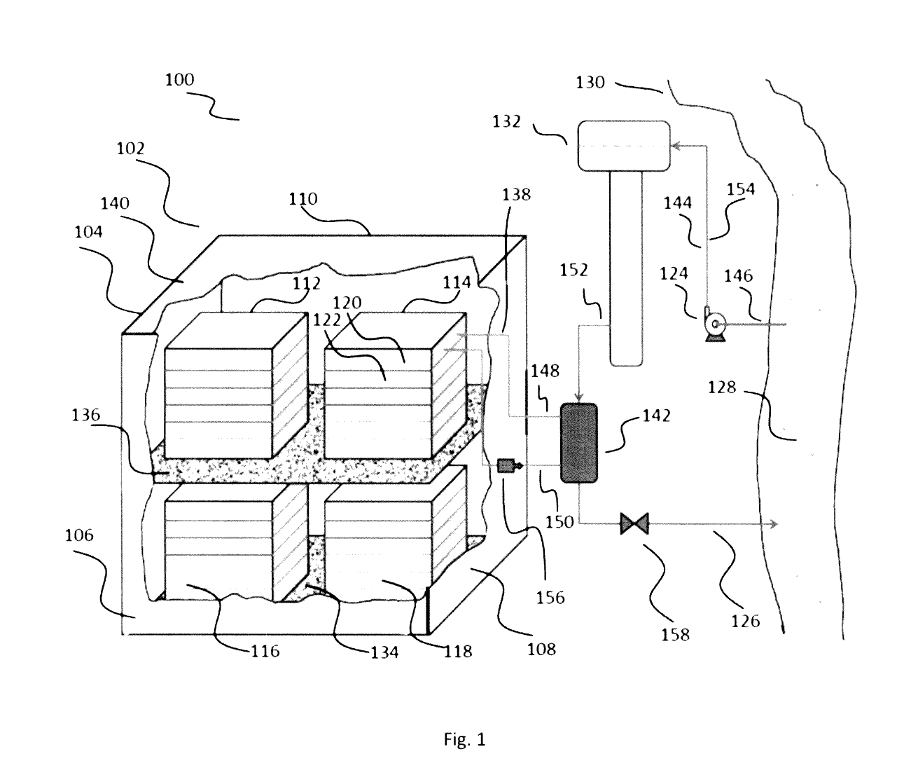

FIG. 1 schematically illustrates a cooling system 100 in accordance with one embodiment of the present invention. The cooling system 100 generally comprises a building 102 configured to accommodate computers. The cooling system 100 further comprises a river 130 in connection with the building 102 via a cooling water tower 132, liquid-liquid heat exchanger 142, cooling water conduit 152, drain conduit 126, pump outlet conduit 144, and pump inlet conduit 146.

The building 102 generally comprises a left sidewall 104, a front sidewall 106, a right sidewall 108, back sidewall 110, and roof 140. In one embodiment, the building 102 comprises first floor 134 and second floor 136.

The cooling system 100 comprises server rack 116 and server rack 118 on first floor 134. The cooling system 100 also includes server rack 112 and server rack 114 on second floor 136. A server rack usually accommodates multiple servers. In one embodiment, server rack 114 accommodates server 120 and server 122.

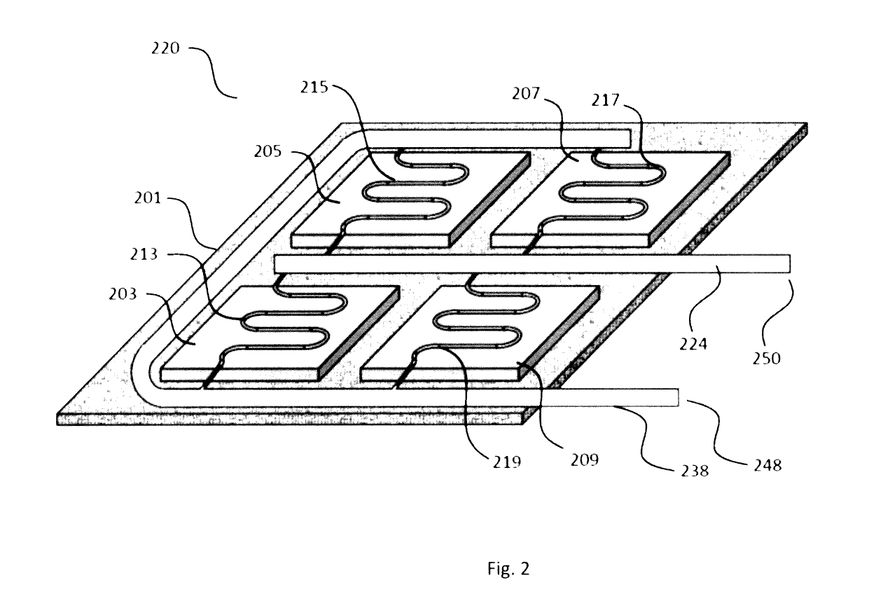

The cooling system 100 is configured to position a cooling liquid supply conduit 148 to flow cooling liquid 138 into server 120 and carry heat out of server 120 by flowing cooling liquid 138 out of server 120 in return conduit 150. The cooling liquid supply conduit 148 and return conduit 150 are connected to a liquid-liquid heat exchanger 142. The chip contact details will be further described below with references in FIG. 2. The heat exchanger 142 dissipates heat in the cooling liquid 138 to cooling water 154. In one embodiment, one end of the liquid-liquid heat exchanger 142 is configured to be connected with cooling water tower 132 for taking cooling water 154 and the other end is connected to river for draining cooling water 154.

During cooling process, the supply conduit 148 has a higher pressure compared with return conduit 150 to ensure the flow rate for cooling performance. The cooling liquid 138 in the supply conduit 148 has a lower temperature than the cooling liquid 138 in return conduit 150. The cooling liquid 138 in return conduit 150 transfers heat out of server 120 to cooling water 154 in liquid-liquid heat exchanger 142. During the cooling liquid 138 flowing through heat exchanger 142, temperature of cooling liquid 138 keeps falling, and attains such a low temperature when flowing out of the heat exchanger 142 that the temperature meets the requirement for flowing into heat-generating components in server 120.

The heat exchanger 142 can be configured for cooling of one server, or one server rack, or multiple server racks. When heat exchanger 142 is used for cooling of multiple servers, the constant pressures in supply conduit 148 and return conduit 150 should be kept well. The cooling liquid 138 should be stable and bubbles are not allowed in order to ensure the quality of cooling and heat exchanging.

The liquid-liquid heat exchanger 142 may have high heat exchange efficiency due to the high density of liquid. The temperature difference between supply conduit 148 and return conduit 150 is low to avoid high temperature variation in heat-generating components in computer system. Typical temperature difference between these two conduits is 10-30° C. The circulation of cooling liquid 138 is driven by a pump 156 in order to have acceptable heat exchanging rate on the surface of heat-exchanging components.

During cooling processing of one embodiment, cooling water 154 is sucked from the river 130. For data center located in north cold area, the pump inlet conduit 146 should be well protected from freezing because it may damage the pipe system. In one embodiment, the pump inlet conduit 146 is laid underground to avoid freezing in winter. Similarly, pump 124, tower 132, conduits 144, 152, and 126 should be protected well during winter for data center located in north area.

According to one embodiment of the invention, the elevation of cooling water 154 in cooling tower 132 should be automatically controlled the same all the time. This can be controlled by a continuous operation mode of cooling water pump 124, or non-continuous operation mode, depending on the design. After data center facility is in operation, the cooling water flow rate is mainly determined by water level of the cooling water 154 in cooling water tower 132. In one embodiment, a regulating valve 158 is used to adjust the flow rate of cooling water 154 in the liquid-liquid heat exchanger 142 by varying the opening.

In one embodiment, a grate and filter is used at one end of cooling water inlet conduit 146 to keep the contaminants out of the cooling system. In addition, the elevation of one end of cooling water conduit 146 for sucking water in the river 130 should be adjusted according to the level of river, especially in the north area where river water level changes with season significantly.

For convenience of operation, the building 102 should be located close to the river 130 to reduce the length of the conduits. To ensure the performance of cooling system 100, the river current 128 should be high enough for cooling of a data center. Generally, the river stream 128 should have a discharge of 40 m³/s or higher for cooling of a large data center.

In one embodiment, the cooling liquid 138 is deionized water. In another embodiment, the cooling liquid 138 is oil or ionic liquid.

FIG. 2 schematically illustrates an enlarged view of the server 220 disposed in the server rack 114 of FIG. 1. The server 220 includes the board 201 configured to accommodate components. The board 201 supplies mechanical holding to components and electrical interconnection among the devices. The board 201 can be a printed circuit board (PCB) or silicon interposer. In one embodiment, the board 201 holds a microprocessor unit (MPU) 203, a memory package 205, a power-supply chip 207, and a memory storage 209. The server 220 also accommodates supply conduit 248, return conduit 250, MPU cooling conduit 213, memory cooling conduit 215, power cooling conduit 217, and store cooling conduit 219, wherein cooling liquid 238 flows for heat exchanging.

The cross-sectional areas of liquid conduits may vary for cooling effectiveness. In one embodiment, the cross-sectional areas of supply conduit 248 and return conduit 250 are significantly larger than those of MPU cooling conduit 213, memory cooling conduit 215, power cooling conduit 217, and store cooling conduit 219.

During cooling processing, the cooling liquid 238 is circulated in a closed loop shown in FIG. 1. Liquid conduits shown in FIG. 2 are part of the total closed loop. In order to have effective heat exchanges between devices and the cooling liquid 238, moderate flow rate in heat-generating components should be kept. Generally, the turbulent flow in MPU conduit 213, memory conduit 215, power conduit 217, and storage conduit 219 should be maintained. The pump 156 shown in FIG. 1 drives the flow rate and ensures the effectiveness of heat dissipation.

Heat dissipation makes temperature in the return conduit 250 is higher than that in the supply conduit 248. The higher temperature difference between these two conduits means more energy carried out at a same flow rate. However, low temperature difference should be kept in order to have a more uniform temperature on the heat-generating components. The non-uniformity of temperature may introduce extra stress, resulting in reliability issues. Typical temperature difference between the supply conduit 248 and return conduit 250 is about 20° C.

MPUs consume most power in a computer system. Effective contact between the MPU conduit 213 and the MPU 203 is the key to cool the MPU. The plane ship of the MPU 203 generally makes the realization of thermal contact easy. However, common memory is packaged in single in-line memory module (SIMM) or dual in-line memory module (DIMM), which has a non-plane shape, resulting in challenges in thermal contact effectiveness.

Recently, three dimensional integrated circuit (3D IC) stacked by using through silicon via (TSV) provides an effective way to make DRAM package have a plane geometry. In one embodiment of this disclosure, stacked DRAM as the memory package 205 is used for the server 220. Therefore, the memory package 205 has a plane for obtaining effective thermal contact between the cooling liquid 238 and the memory package 205.

Generally, power chip 207 is attached to a large radiator for dissipating heat into air. In one embodiment of this invention, power conduit will 217 will attached to the power chip 217 for effective heat dissipation.

Sometime, a server includes the storage 209. In one embodiment, the storage 209 is a solid-state storage. In another embodiment, the storage 209 is a hard driver. In any case, storage conduit 219 will provide effective heat dissipation.

In one embodiment, heat-generating components are modules, but there are some passive components which release small amount of heat. For cooling this heat, a cooling conduit may be thermally contacted with the motherboard or interposer to dissipate it.

While the foregoing is directed to embodiments of the present invention, other and further embodiments of the invention may be devised without departing from the basic scope thereof, and the scope thereof is determined by the claims that follow.

What is claimed is:

1. A cooling system for a plural of heat-generating components in a computer system, comprising
a. One or plural of heat-exchanging channels configured to be placed in thermal contact with said heat-generating components;
b. A liquid-liquid heat exchanger including a first exchanger conduit and a second exchanger conduit wherein a first liquid coolant flows in said first exchanger conduit and a cooling water flows in said second exchanger conduit; heat is dissipated from said first liquid coolant in said first exchanger conduit to said cooling water in said second exchanger conduit;
c. A closed conduit including a supply conduit, said heat-exchanging channels, a return conduit, and said first exchanger conduit of said liquid-liquid heat-exchanger; wherein said first liquid coolant is configured to be circulated in said closed conduit; said supply conduit is configured to flow said first liquid coolant into said heat-exchanging channels, a return conduit is configured to flow said first liquid coolant out of said heat-exchanging channels; said supply conduit and said return conduit have larger cross-sectional areas for flowing of said first liquid coolant than sum of cross-sectional areas of said heat-exchanging channels;
d. A first pump configured to drive circulating of said first liquid coolant in said closed conduit;
e. A water tower configured to have an elevated water level higher than the elevation of a large water body; wherein a second pump is configured to pump said cooling water from said large water body into said water tower; a drain outlet is configured at a lower elevation than said elevated water level to flow said cooling water out of said water tower;
f. A cooling conduit configured to connect said drain outlet to a first end of said second conduit of said liquid-liquid heat exchanger to flow said cooling water from said water tower into said liquid-liquid heat exchanger;
g. A back conduit configured to connect a second end of said second conduit of said liquid-liquid heat exchanger to said large water body to flow said cooling water from said liquid-liquid heat exchanger to said large water body;

2. The cooling system of claim 1, wherein said large water body is a river.

3. The cooling system of claim 1, wherein said large water body is a reservoir.

4. The cooling system of claim 1, wherein said large water body is an ocean.

5. The cooling system of claim 1, wherein said first liquid coolant is water.

6. The cooling system of claim 1, wherein said first liquid coolant is oil.

7. The cooling system of claim 1, wherein said first liquid coolant is ionic liquid.

8. The cooling system of claim 1, wherein said heat-generating components include microprocessor, dynamic random access memory, and power supply chip.

9. The cooling system of claim 1, wherein said computer system is a server.

10. The cooling system of claim 1, wherein said elevated water level is at least two meters higher than the elevation of said large water body.

11. A cooling method for a plural of heat-generating components in a computer system, comprising
a. Providing a component liquid conduit having thermal contact with said heat-generating components;
b. Providing a liquid-liquid heat exchanger having a first heat-exchanging conduit and a second heat-exchanging conduit;
c. Circulating a first coolant in said component liquid conduit and in said first heat-exchanging conduit for carrying out heat from said heat-generating components and dissipating heat to said first coolant;
d. Providing a means for said first coolant having a controllable flow rate on said component liquid conduits;
e. Dissipating heat from said first coolant in said first heat-exchanging conduit to a cooling water flowing in said second heat-exchanging conduit in said liquid-liquid heat exchanger;
f. Providing a means adjusting flow rate in said second heat-exchanging conduit;
g. Taking said cooling water from a large water body and flowing said cooling water to a first end of said second heat-exchanging conduit of said liquid-liquid heat exchanger;
h. Draining said cooling water from a second end of said heat-exchanging conduit to said large water body;

12. The cooling system of claim 11, wherein said large water body is a river.

13. The cooling system of claim 11, wherein said large water body is a reservoir.

14. The cooling system of claim 11, wherein said large water body is an ocean.

15. The cooling system of claim 11, wherein said first coolant is water.

16. The cooling system of claim 11, wherein said first coolant is oil.

17. The cooling system of claim 11, wherein said first coolant is ionic liquid.

18. The cooling system of claim 11, wherein said controllable flow rate is realized by using a water tower and a valve.

19. The cooling system of claim 11, wherein said computer system is a server.

20. The cooling system of claim 11, wherein said heat-generating components include microprocessor, dynamic random access memory, solid-state drive, hard drive, and power-supply chip.
